(19) United States
(12) Patent Application Publication
(10) Pub. No.: US 2025/0228016 A1
(43) Pub. Date: Jul. 10, 2025

(54) SEMICONDUCTOR DEVICE STRUCTURE AND METHOD FOR FORMING THE SAME

(71) Applicant: TAIWAN SEMICONDUCTOR MANUFACTURING COMPANY, LTD., Hsinchu (TW)

(72) Inventors: Chen-Hao CHIANG, Taoyuan City (TW); Li-Weng CHANG, New Taipei City (TW); Jiun-Yi WU, Taoyuan City (TW); Chen-Hua YU, Hsinchu City (TW)

(73) Assignee: TAIWAN SEMICONDUCTOR MANUFACTURING COMPANY, LTD., Hsinchu (TW)

(21) Appl. No.: 18/404,394

(22) Filed: Jan. 4, 2024

(51) Int. Cl. H01L 31/107; H01L 31/0232; H01L 31/0352; H01L 31/18

(52) U.S. Cl. CPC H10F 30/2255; H10F 71/121; H10F 77/148; H10F 77/413

(57) ABSTRACT

A semiconductor device structure is provided. The semiconductor device structure includes a substrate including a P-type region and an N-type region. The P-type region and the N-type region are spaced apart from each other. The semiconductor device structure includes a light absorption structure in the substrate between the P-type region and an N-type region. The semiconductor device structure includes a first P-type film between the light absorption structure and the P-type region. The semiconductor device structure includes a second P-type film between the light absorption structure and the N-type region, wherein a portion of the substrate separates the second P-type film from the N-type region.

### BACKGROUND

The semiconductor integrated circuit (IC) industry has experienced rapid growth. Technological advances in IC materials and design have produced generations of ICs. Each generation has smaller and more complex circuits than the previous generation. However, these advances have increased the complexity of processing and manufacturing ICs.

In the course of IC evolution, functional density (i.e., the number of interconnected devices per chip area) has generally increased while geometric size (i.e., the smallest component (or line) that can be created using a fabrication process) has decreased.

However, as functional density continues to increase, the number of signals that need to be transmitted continues to increase. Therefore, light is used to transmit signals. As a result, forming reliable semiconductor devices to detect and convert optical signals into electrical signals is a challenge.

### BRIEF DESCRIPTION OF THE DRAWINGS

Aspects of the present disclosure are best understood from the following detailed description when read with the accompanying figures. It should be noted that, in accordance with standard practice in the industry, various features are not drawn to scale. In fact, the dimensions of the various features may be arbitrarily increased or reduced for clarity of discussion.

FIGS. 1A-1E are cross-sectional views of various stages of a process for forming a semiconductor device structure, in accordance with some embodiments.

FIGS. 1A-1 to 1E-1 are top views of the semiconductor device structures of FIGS. 1A-1E, in accordance with some embodiments.

FIG. 1A-2 is a cross-sectional view illustrating the semiconductor device structure along a sectional line II-II′ in FIG. 1A-1, in accordance with some embodiments.

FIG. 1A-3 is a cross-sectional view illustrating the semiconductor device structure along a sectional line II-II′ in FIG. 1A-1, in accordance with some other embodiments.

FIG. 1E-2 is a cross-sectional view illustrating the semiconductor device structure along a sectional line II-II′ in FIG. 1E-1, in accordance with some embodiments.

FIG. 2 is a cross-sectional view illustrating a semiconductor device structure, in accordance with some embodiments.

### DETAILED DESCRIPTION

The following disclosure provides many different embodiments, or examples, for implementing different features of the subject matter provided. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Furthermore, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

Some embodiments of the disclosure are described. Additional operations can be provided before, during, and/or after the stages described in these embodiments. Some of the stages that are described can be replaced or eliminated for different embodiments.

Additional features can be added to the semiconductor device structure. Some of the features described below can be replaced or eliminated for different embodiments. Although some embodiments are discussed with operations performed in a particular order, these operations may be performed in another logical order.

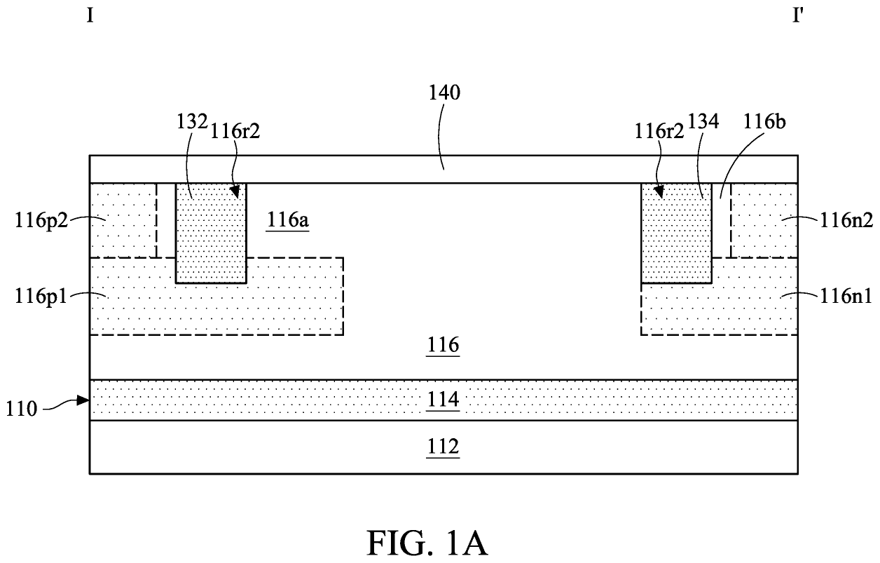

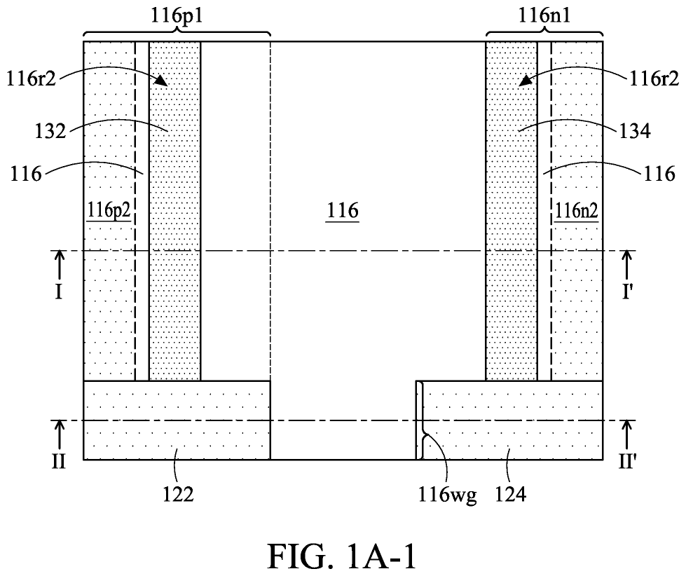

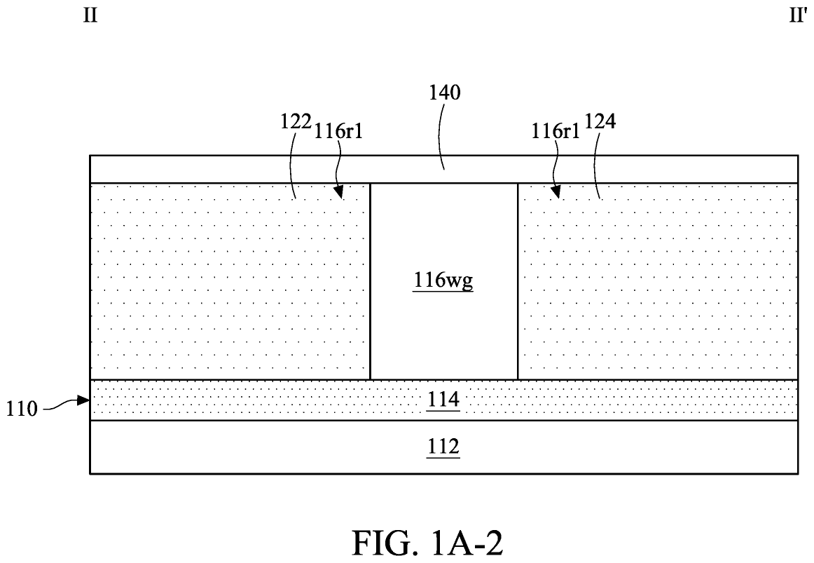

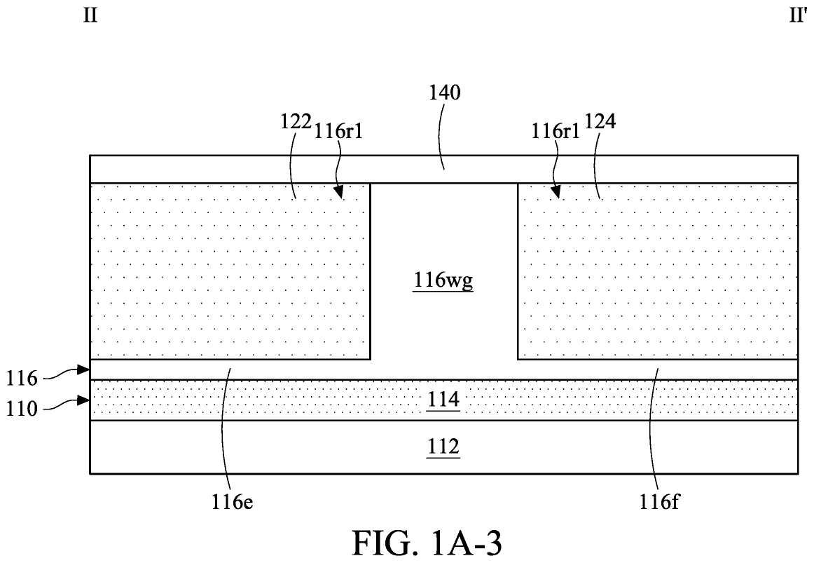

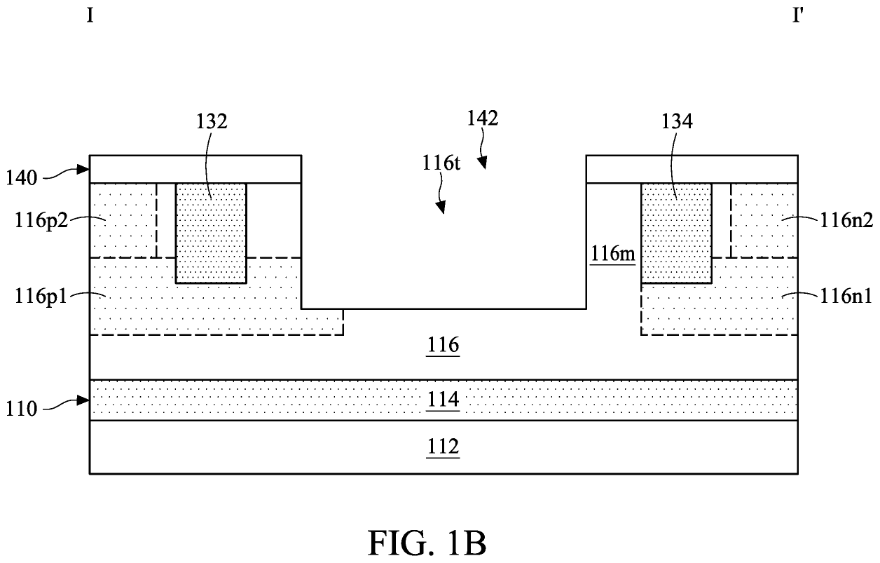

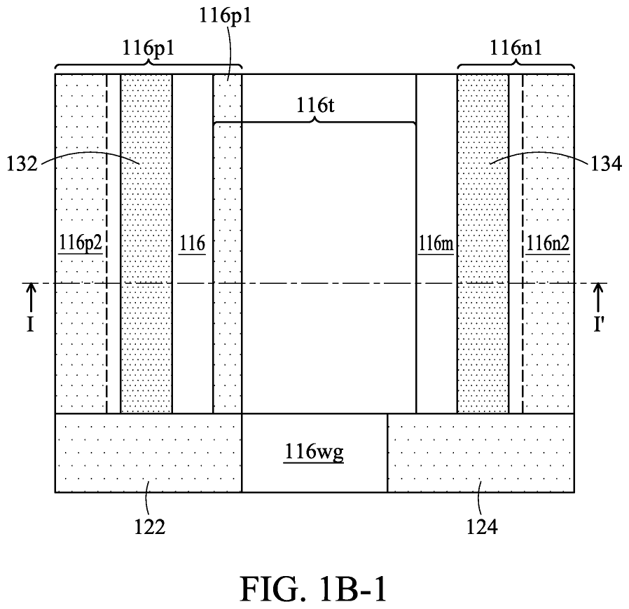

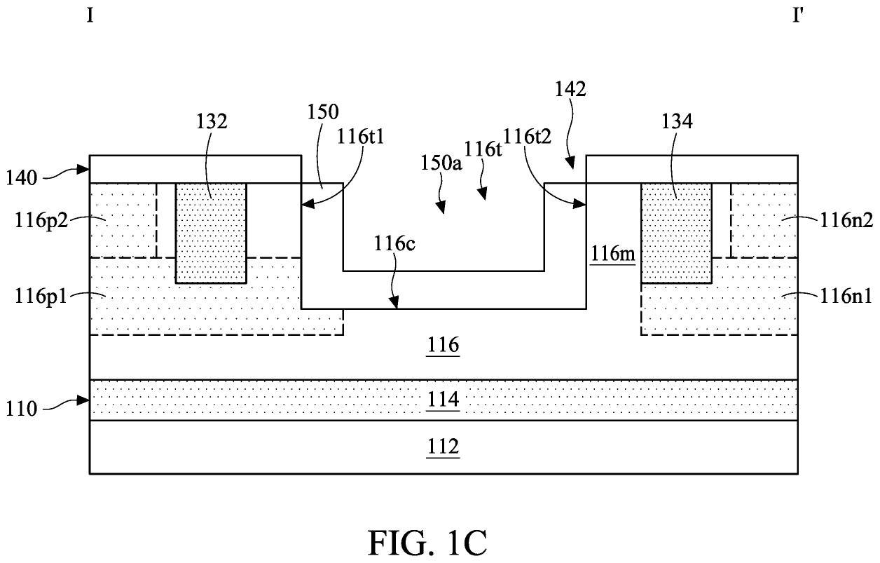

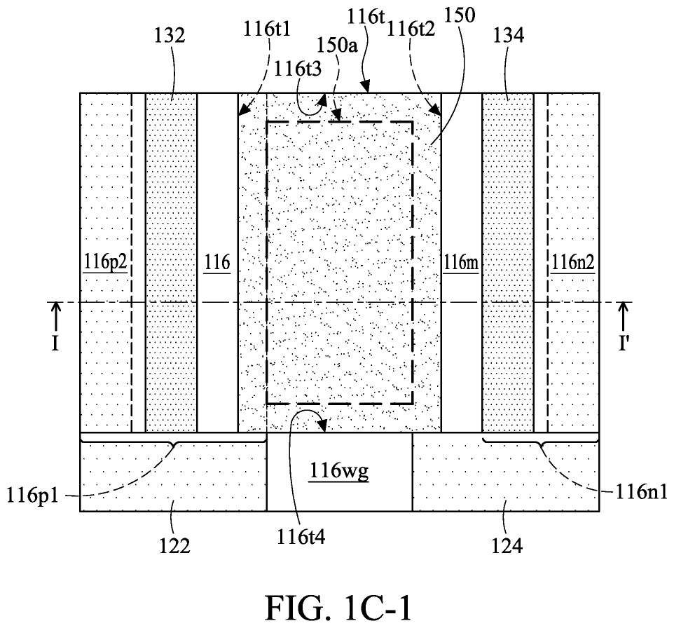

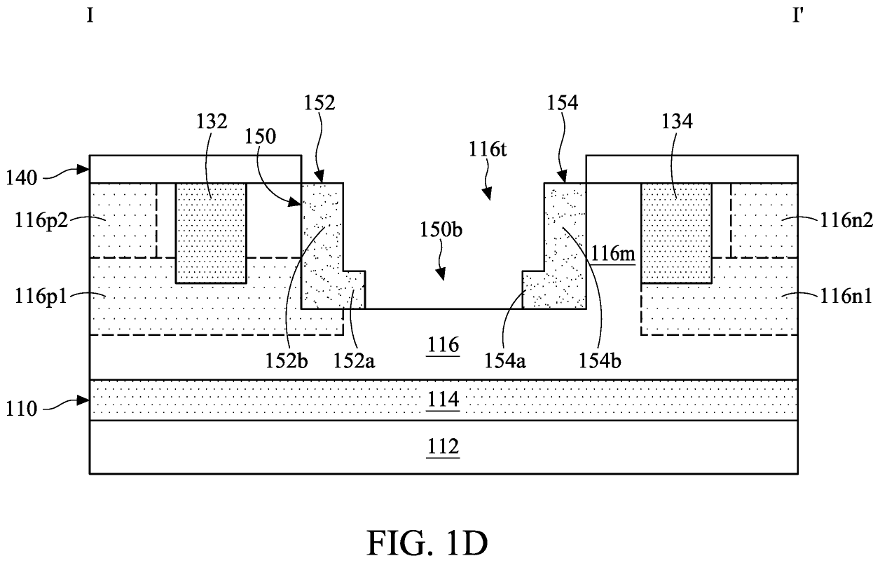

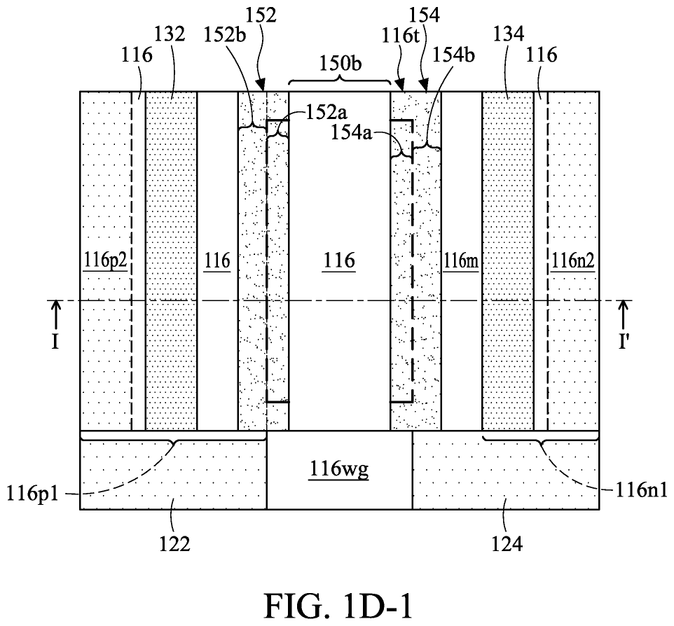

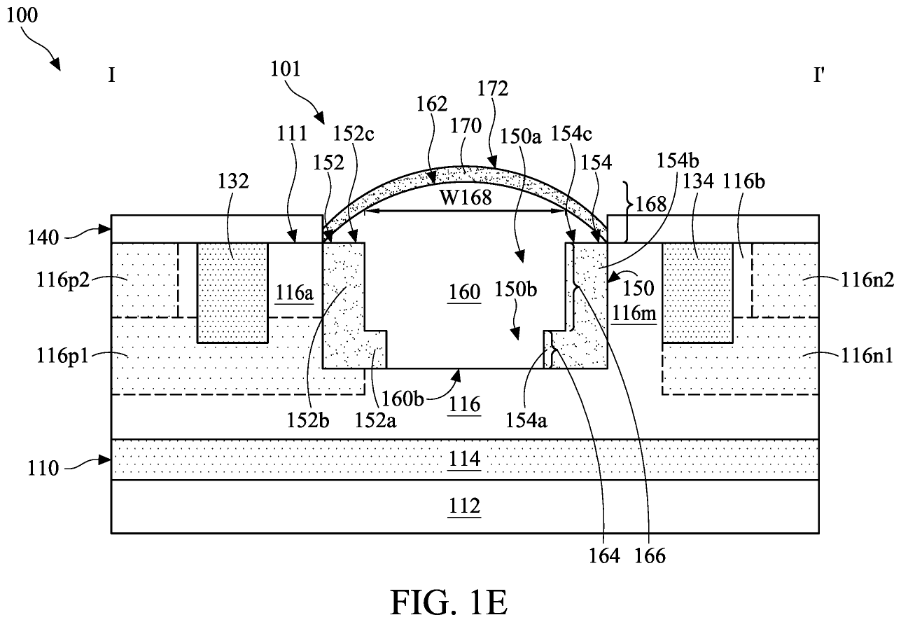

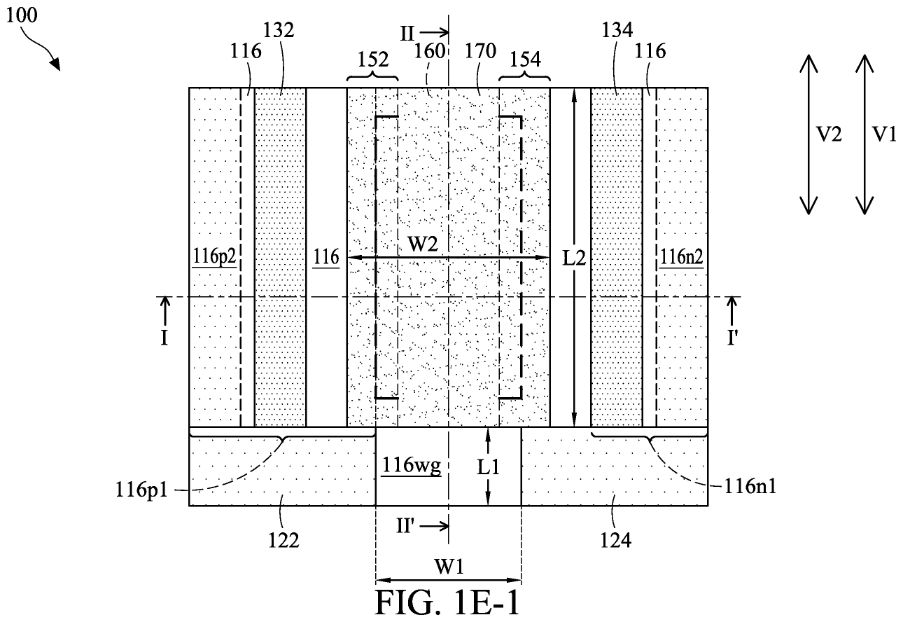

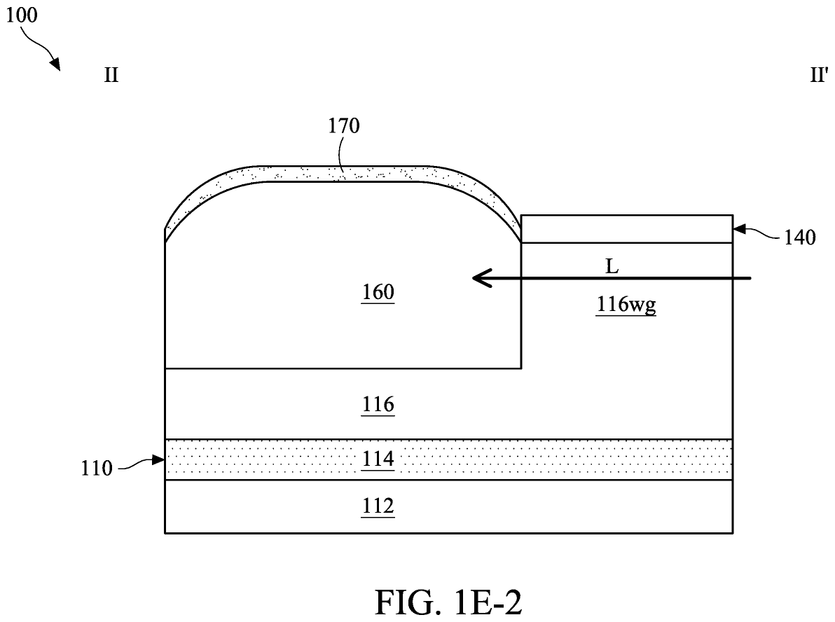

FIGS. 1A-1E are cross-sectional views of various stages of a process for forming a semiconductor device structure, in accordance with some embodiments. FIGS. 1A-1 to 1E-1 are top views of the semiconductor device structures of FIGS. 1A-1E, in accordance with some embodiments.

As shown in FIGS. 1A and 1A-1, a substrate 110 is provided, in accordance with some embodiments. The substrate 110 includes, for example, a wafer or a portion of a wafer. The substrate 110 includes, for example, a semiconductor-on-insulator (SOI) substrate (such as silicon on insulator or germanium on insulator).

The substrate 110 has a semiconductor layer 112, an insulating layer 114, and a semiconductor layer 116, in accordance with some embodiments. The insulating layer 114 is over the semiconductor layer 112, in accordance with some embodiments. The semiconductor layer 116 is over the insulating layer 114, in accordance with some embodiments.

In some embodiments, the semiconductor layers 112 and 116 are made of an elementary semiconductor material including silicon or germanium in a single crystal structure, a polycrystal structure, or an amorphous structure. In some other embodiments, the semiconductor layers 112 and 116 are made of a compound semiconductor, such as silicon carbide, gallium arsenide, gallium phosphide, indium phosphide, indium arsenide, an alloy semiconductor, such as SiGe or GaAsP, or a combination thereof.

In some embodiments, the substrate 110 is a device wafer that includes various device elements. In some embodiments, the various device elements are formed in and/or over the substrate 110. The device elements are not shown in figures for the purpose of simplicity and clarity.

Examples of the various device elements include active devices, passive devices, other suitable elements, or a combination thereof. The active devices may include transistors or diodes (not shown) formed at a surface of the substrate 110. The passive devices include resistors, capacitors, or other suitable passive devices.

For example, the transistors may be metal oxide semiconductor field effect transistors (MOSFET), complementary metal oxide semiconductor (CMOS) transistors, bipolar junction transistors (BJT), high-voltage transistors, high-frequency transistors, p-channel and/or n-channel field effect transistors (PFETs/NFETs), etc.

Various processes, such as front-end-of-line (FEOL) semiconductor fabrication processes, are performed to form the various device elements. The FEOL semiconductor fabrication processes may include deposition, etching, implantation, photolithography, annealing, planarization, one or more other applicable processes, or a combination thereof.

In some embodiments, isolation features (not shown) are formed in the substrate 110. The isolation features are used to surround active regions and electrically isolate various device elements formed in and/or over the substrate 110 in the active regions. In some embodiments, the isolation features include shallow trench isolation (STI) features, local oxidation of silicon (LOCOS) features, other suitable isolation features, or a combination thereof.

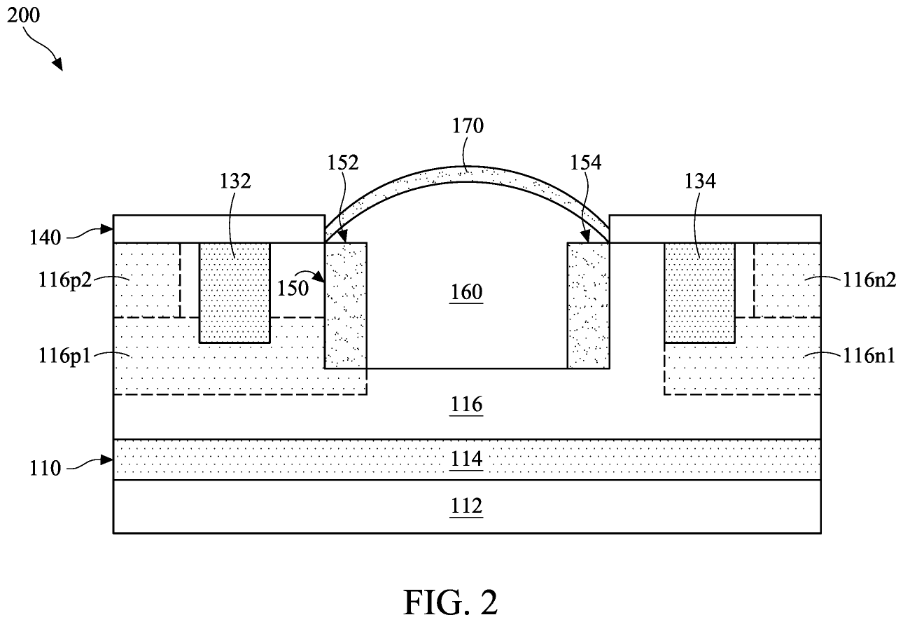

FIG. 1A-2 is a cross-sectional view illustrating the semiconductor device structure along a sectional line II-II′ in FIG. 1A-1, in accordance with some embodiments. As shown in FIGS. 1A-1 and 1A-2, portions of the semiconductor layer 116 are removed to form trenches 116r1 in the semiconductor layer 116, in accordance with some embodiments.

The trenches 116r1 pass through the semiconductor layer 116 and expose the insulating layer 114, in accordance with some embodiments. The removal process includes a photolithography process and an etching process, in accordance with some embodiments. As shown in FIGS. 1A-1 and 1A-2, insulating structures 122 and 124 are formed in the trenches 116r1, in accordance with some embodiments. As shown in FIGS. 1A-1 and 1A-2, a waveguide portion 116wg of the semiconductor layer 116 is between the insulating structures 122 and 124, in accordance with some embodiments.

The insulating structures 122 and 124 are made of insulating materials, such as silicon oxide, silicon nitride, silicon oxynitride, silicon carbide, borosilicate glass (BSG), phosphoric silicate glass (PSG), borophosphosilicate glass (BPSG), fluorinated silicate glass (FSG), a low-k material, a porous dielectric material, or a combination thereof, in accordance with some embodiments. The insulating structures 122 and 124 are formed using a deposition process and a chemical mechanical polishing process, in accordance with some embodiments.

FIG. 1A-3 is a cross-sectional view illustrating the semiconductor device structure along a sectional line II-II′ in FIG. 1A-1, in accordance with some other embodiments. In some other embodiments, as shown in FIG. 1A-3, the insulating structures 122 and 124 do not pass through the semiconductor layer 116.

The portion 116e of the semiconductor layer 116 is between the insulating structure 122 and the insulating layer 114, in accordance with some embodiments. The portion 116f of the semiconductor layer 116 is between the insulating structure 124 and the insulating layer 114, in accordance with some embodiments.

As shown in FIGS. 1A and 1A-1, portions of the semiconductor layer 116 are removed to form trenches 116r2 in the semiconductor layer 116, in accordance with some embodiments. The removal process includes a photolithography process and an etching process, in accordance with some embodiments.

Thereafter, as shown in FIGS. 1A and 1A-1, isolation structures 132 and 134 are formed in the trenches 116r2 in the semiconductor layer 116, in accordance with some embodiments. The isolation structures 132 and 134 are made of insulating materials, such as silicon oxide, silicon nitride, silicon oxynitride, silicon carbide, borosilicate glass (BSG), phosphoric silicate glass (PSG), borophosphosilicate glass (BPSG), fluorinated silicate glass (FSG), a low-k material, a porous dielectric material, or a combination thereof, in accordance with some embodiments. The isolation structures 132 and 134 are formed using a deposition process and a chemical mechanical polishing process, in accordance with some embodiments.

Thereafter, as shown in FIGS. 1A and 1A-1, a P-type region 116p1 and an N-type region 116n1 are formed in the semiconductor layer 116, in accordance with some embodiments. The P-type region 116p1 and the N-type region 116n1 are spaced apart from each other, in accordance with some embodiments.

As shown in FIG. 1A, the isolation structure 132 passes through a part 116a of the semiconductor layer 116 over the P-type region 116p1, and the isolation structure 134 passes through a part 116b of the semiconductor layer 116 over the N-type region 116n1, in accordance with some embodiments.

The P-type region 116p1 is doped with a P-type dopant such as boron (B), aluminum (Al), indium (In), or gallium (Ga), in accordance with some embodiments. The N-type region 116n1 is doped with an N-type dopant such as phosphorus (P), arsenic (As), or antimony (Sb), in accordance with some embodiments. The P-type region 116p1 and the N-type region 116n1 are formed using implantation processes, in accordance with some embodiments.

As shown in FIGS. 1A and 1A-1, a heavily P-type doped region 116p2 and a heavily N-type doped region 116n2 are formed in the semiconductor layer 116, in accordance with some embodiments. The heavily P-type doped region 116p2 is over and connected to the P-type region 116p1, in accordance with some embodiments. The heavily N-type doped region 116n2 is over and connected to the N-type region 116n1, in accordance with some embodiments.

The heavily P-type doped region 116p2 is doped with a P-type dopant such as boron (B), aluminum (Al), indium (In), or gallium (Ga), in accordance with some embodiments. The heavily N-type doped region 116n2 is doped with an N-type dopant such as phosphorus (P), arsenic (As), or antimony (Sb), in accordance with some embodiments.

The P-type dopant concentration of the heavily P-type doped region 116p2 is greater than that of the P-type region 116p1, in accordance with some embodiments. The N-type dopant concentration of the heavily N-type doped region 116n2 is greater than that of the N-type region 116n1, in accordance with some embodiments. The heavily P-type doped region 116p2 and the heavily N-type doped region 116n2 are formed using implantation processes, in accordance with some embodiments.

Afterwards, as shown in FIGS. 1A and 1A-2, an insulating layer 140 is formed over the substrate 110, the insulating structures 122 and 124, and the isolation structures 132 and 134, in accordance with some embodiments. It should be noted that, for the sake of simplicity, FIGS. 1A-1 to 1E-1 do not show the insulating layer 140, in accordance with some embodiments.

The insulating layer 140 is made of insulating materials, such as silicon oxide, silicon nitride, silicon oxynitride, silicon carbide, borosilicate glass (BSG), phosphoric silicate glass (PSG), borophosphosilicate glass (BPSG), fluorinated silicate glass (FSG), a low-k material, a porous dielectric material, or a combination thereof, in accordance with some embodiments. The insulating layer 140 is formed using a deposition process, in accordance with some embodiments.

As shown in FIGS. 1B and 1B-1, the insulating layer 140 and the semiconductor layer 116 between the P-type region 116p1 and the N-type region 116n1 are partially removed to form an opening 142 in the insulating layer 140 and a trench 116t in the semiconductor layer 116, in accordance with some embodiments.

The opening 142 is over the trench 116t, in accordance with some embodiments. The trench 116t exposes the P-type region 116p1, in accordance with some embodiments. The trench 116t extends into the P-type region 116p1, in accordance with some embodiments. The removal process includes a photolithography process and an etching process, in accordance with some embodiments.

As shown in FIGS. 1C and 1C-1, a P-type layer 150 is formed in the trench 116t in the semiconductor layer 116, in accordance with some embodiments. The P-type layer 150 is conformally formed in the trench 116t, in accordance with some embodiments. The P-type layer 150 conformally covers inner walls 116t1, 116t2, 116t3, and 116t4 and a bottom surface 116c of the trench 116t, in accordance with some embodiments. The P-type layer 150 has a recess 150a in the trench 116t, in accordance with some embodiments.

As shown in FIGS. 1C and 1C-1, a multiplication portion 116m of the semiconductor layer 116 is between the P-type layer 150 and the N-type region 116n1 and between the P-type layer 150 and the isolation structure 134, in accordance with some embodiments. The multiplication portion 116m separates the P-type layer 150 from the N-type region 116n1, in accordance with some embodiments.

The P-type layer 150 is made of a P-type semiconductor material including a semiconductor material and a P-type dopant, in accordance with some embodiments. The semiconductor material includes silicon, germanium, or the like, in accordance with some embodiments. The P-type dopant includes boron (B), aluminum (Al), indium (In), or gallium (Ga), in accordance with some embodiments. The P-type layer 150 is formed using an epitaxial process, in accordance with some embodiments.

As shown in FIGS. 1C, 1D and 1D-1, the P-type layer 150 is partially removed to form a trench 150b in the P-type layer 150, in accordance with some embodiments. The P-type layer 150 is divided into P-type films 152 and 154 by the trench 150b, in accordance with some embodiments.

The P-type film 152 is on the P-type region 116p1 exposed by the trench 116t, in accordance with some embodiments. The P-type film 152 is connected to the P-type region 116p1, in accordance with some embodiments.

The P-type film 154 is between the P-type film 152 and the N-type region 116n1, in accordance with some embodiments. The P-type films 152 and 154 are spaced apart from each other, in accordance with some embodiments. The P-type film 154 and the N-type region 116n1 are separated from each other by the multiplication portion 116m of the semiconductor layer 116, in accordance with some embodiments.

The P-type film 152 has an L shape, in accordance with some embodiments. The P-type film 152 has a horizontal portion 152a and a vertical portion 152b, in accordance with some embodiments. The P-type film 154 has an L shape, in accordance with some embodiments. The P-type film 154 has a horizontal portion 154a and a vertical portion 154b, in accordance with some embodiments.

The P-type film 152 extends into the P-type region 116p1, in accordance with some embodiments. The isolation structure 132 is between the heavily P-type doped region 116p2 and the P-type film 152, in accordance with some embodiments. The isolation structure 134 is between the heavily N-type doped region 116n2 and the P-type film 154, in accordance with some embodiments. The removal process includes a photolithography process and an etching process, in accordance with some embodiments.

It should be noted that, for the sake of simplicity, FIGS. 1A-1 to 1D-1 show only a part of the waveguide portion 116wg, in accordance with some embodiments. FIG. 1E-1 shows the entire waveguide portion 116wg, in accordance with some embodiments.

As shown in FIGS. 1E and 1E-1, a light absorption structure 160 is formed in the trench 116t in the semiconductor layer 116, in accordance with some embodiments. The light absorption structure 160 is over the P-type films 152 and 154, in accordance with some embodiments. The light absorption structure 160 is in direct contact with the P-type films 152 and 154, in accordance with some embodiments.

The light absorption structure 160 is connected between the P-type films 152 and 154, in accordance with some embodiments. The light absorption structure 160 is between the P-type region 116p1 and the N-type region 116n1, in accordance with some embodiments.

The P-type film 152 is between the light absorption structure 160 and the P-type region 116p1, in accordance with some embodiments. The P-type film 154 is between the light absorption structure 160 and the N-type region 116n1, in accordance with some embodiments.

The top surface 152c of the P-type film 152 is substantially level with the top surface 111 of the substrate 110, in accordance with some embodiments. The top surface 154c of the P-type film 154 is substantially level with the top surface 111 of the substrate 110, in accordance with some embodiments.

The light absorption structure 160 covers the top surface 152c of the P-type film 152 and the top surface 154c of the P-type film 154, in accordance with some embodiments. The light absorption structure 160 has a convex top surface 162, in accordance with some embodiments. The convex top surface 162 is a convex curved surface, in accordance with some embodiments.

The light absorption structure 160 has a lower portion 164, a middle portion 166, and a top portion 168, in accordance with some embodiments. The top portion 168 is wider than the middle portion 166, in accordance with some embodiments. The middle portion 166 is wider than the lower portion 164, in accordance with some embodiments.

The width W168 of the top portion 168 increases toward the substrate 110, in accordance with some embodiments. The width W168 of the top portion 168 continuously increases toward the substrate 110, in accordance with some embodiments.

FIG. 1E-2 is a cross-sectional view illustrating the semiconductor device structure along a sectional line II-II′ in FIG. 1E-1, in accordance with some embodiments. As shown in FIGS. 1E-1 and 1E-2, the waveguide portion 116wg is in direct contact with the light absorption structure 160, which improves the light absorption performance of the light absorption structure 160, in accordance with some embodiments.

As shown in FIG. 1E-1, the width W1 of the waveguide portion 116wg is less than the length L1 of the waveguide portion 116wg, in accordance with some embodiments. The length L1 is measured along a longitudinal axis V1 of the waveguide portion 116wg, in accordance with some embodiments.

The width W2 of the light absorption structure 160 is less than the length L2 of the light absorption structure 160, in accordance with some embodiments. The length L2 is measured along a longitudinal axis V2 of the light absorption structure 160, in accordance with some embodiments. The longitudinal axis V1 is substantially parallel to the longitudinal axis V2, in accordance with some embodiments.

The P-type region 116p1, the N-type region 116n1, the heavily P-type doped region 116p2, the heavily N-type doped region 116n2, the P-type films 152 and 154, the light absorption structure 160, and the multiplication portion 116m of the semiconductor layer 116 together form a separate-absorption-charge-multiplication (SACM) avalanche photodetector (APD) 101, in accordance with some embodiments.

As shown in FIG. 1E-2, the light absorption structure 160 is used to absorb the light L from the waveguide portion 116wg, in accordance with some embodiments. The light can bombard the atoms of the light absorption structure 160 to generate electron-hole pairs, in accordance with some embodiments.

The electrons of the electron-hole pairs are injected into the P-type film 154, in accordance with some embodiments. The P-type film 154 is used as a (signal) charge accelerating layer, in accordance with some embodiments. The electrons in the P-type film 154 are accelerated, in accordance with some embodiments.

Since the P-type film 154 is formed by an epitaxial process (not an implantation process), the thickness of the P-type film 154 can be precisely controlled, which improves the performance of the SACM APD 101, in accordance with some embodiments.

Furthermore, since the P-type films 152 and 154 are spaced apart from the bottom surface 160b of the light absorption structure 160, which prevents the dopants of the P-type films 152 and 154 from diffusing into the light absorption structure 160 from the bottom surface 160b, in accordance with some embodiments.

Therefore, the dopants of the P-type films 152 and 154 diffusing into the light absorption structure 160 are reduced, which improves the performance of the light absorption structure 160, in accordance with some embodiments.

Thereafter, the (accelerated) electrons are injected into the multiplication portion 116m of the semiconductor layer 116, in accordance with some embodiments. The multiplication portion 116m is used as a charge multiplication structure, which can increase the (signal) charges and therefore amplify the electrical signal, in accordance with some embodiments.

Since the multiplication portion 116m is made of silicon, which has a very low impact ionization coefficient (about 0.01), the excess noise resulting from the multiplication portion 116m is reduced, which improves the signal/noise ratio of the SACM APD 101, in accordance with some embodiments.

The light absorption structure 160 is made of a semiconductor material such as germanium, in accordance with some embodiments. The light absorption structure 160 is formed using an epitaxial process, in accordance with some embodiments.

Since the P-type films 152 and 154 are formed by an epitaxial process (not an implantation process), the P-type films 152 and 154 have a high-quality crystal structure, which can help the light absorption structure 160 to have a high-quality crystal structure, in accordance with some embodiments. Therefore, the performance of the light absorption structure 160 is improved, in accordance with some embodiments.

Afterwards, as shown in FIGS. 1E, 1E-1 and 1E-2, a cap layer 170 is formed over the light absorption structure 160, in accordance with some embodiments. The cap layer 170 conformally covers the light absorption structure 160, in accordance with some embodiments. The cap layer 170 is in direct contact with the light absorption structure 160, in accordance with some embodiments.

The cap layer 170 is in direct contact with the insulating layer 140, in accordance with some embodiments. The cap layer 170 has a convex top surface 172, in accordance with some embodiments. The convex top surface 172 is a convex curved surface, in accordance with some embodiments. The cap layer 170 is used to protect the light absorption structure 160 from damage, in accordance with some embodiments.

The cap layer 170 is made of a semiconductor material such as silicon, in accordance with some embodiments. The cap layer 170 is formed using an epitaxial process, in accordance with some embodiments. In this step, a semiconductor device structure 100 is substantially formed, in accordance with some embodiments.

FIG. 2 is a cross-sectional view illustrating a semiconductor device structure 200, in accordance with some embodiments. As shown in FIG. 2, the semiconductor device structure 200 is similar to the semiconductor device structure 100 of FIG. 1E, except that the P-type film 152 of the semiconductor device structure 200 does not have the horizontal portion 152a, and the P-type film 154 of the semiconductor device structure 200 does not have the horizontal portion 154a, in accordance with some embodiments.

The P-type film 152 has a substantially rectangular shape, in accordance with some embodiments. The P-type film 154 has a substantially rectangular shape, in accordance with some embodiments.

Processes and materials for forming the semiconductor device structure 200 may be similar to, or the same as, those for forming the semiconductor device structure 100 described above. Elements designated by the same reference numbers as those in FIGS. 1A to 2 have structures and materials that are the same or similar. Therefore, the detailed descriptions thereof will not be repeated herein.

In accordance with some embodiments, semiconductor device structures and methods for forming the same are provided. The methods (for forming the semiconductor device structure) form P-type films between a light absorption structure and a P-type region and between the light absorption structure and an N-type region using an epitaxial process. Since the P-type films are formed by the epitaxial process (not an implantation process), the thickness of the P-type films can be precisely controlled, which improves the performance of the semiconductor device structures.

In accordance with some embodiments, a semiconductor device structure is provided. The semiconductor device structure includes a substrate including a P-type region and an N-type region. The P-type region and the N-type region are spaced apart from each other. The semiconductor device structure includes a light absorption structure in the substrate between the P-type region and an N-type region. The semiconductor device structure includes a first P-type film between the light absorption structure and the P-type region. The semiconductor device structure includes a second P-type film between the light absorption structure and the N-type region, wherein a portion of the substrate separates the second P-type film from the N-type region.

In accordance with some embodiments, a semiconductor device structure is provided. The semiconductor device structure includes a substrate including a P-type region and an N-type region. The P-type region and the N-type region are spaced apart from each other. The semiconductor device structure includes a first P-type film in the substrate and connected to the P-type region. The semiconductor device structure includes a second P-type film in the substrate and between the first P-type film and the N-type region. The second P-type film is spaced apart from the N-type region. The semiconductor device structure includes a light absorption structure in the substrate and connected between the first P-type film and the second P-type film.

In accordance with some embodiments, a method for forming a semiconductor device structure is provided. The method includes forming a P-type region and an N-type region in a substrate. The P-type region and the N-type region are spaced apart from each other. The method includes partially removing the substrate between the P-type region and the N-type region to form a first trench in the substrate. The first trench exposes the P-type region. The method includes forming a first P-type film and a second P-type film in the first trench. The first P-type film is on the P-type region exposed by the first trench, the second P-type film is between the first P-type film and the N-type region, the first P-type film and the second P-type film are spaced apart from each other, and the second P-type film and the N-type region are separated from each other by a portion of the substrate. The method includes forming a light absorption structure in the first trench and over the first P-type film and the second P-type film.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A semiconductor device structure, comprising:
a substrate comprising a P-type region and an N-type region, wherein the P-type region and the N-type region are spaced apart from each other;
a light absorption structure in the substrate between the P-type region and an N-type region;
a first P-type film between the light absorption structure and the P-type region; and
a second P-type film between the light absorption structure and the N-type region, wherein a portion of the substrate separates the second P-type film from the N-type region.

2. The semiconductor device structure as claimed in claim 1, further comprising:
a first isolation structure passing through a first part of the substrate over the P-type region; and
a second isolation structure passing through a second part of the substrate over the N-type region.

3. The semiconductor device structure as claimed in claim 2, wherein the substrate further comprises:
a heavily P-type doped region over and connected to the P-type region, wherein the first isolation structure is between the heavily P-type doped region and the first P-type film; and
a heavily N-type doped region over and connected to the N-type region, wherein the second isolation structure is between the heavily N-type doped region and the second P-type film.

4. The semiconductor device structure as claimed in claim 3, further comprising:
an insulating layer over the substrate, the first isolation structure, and the second isolation structure.

5. The semiconductor device structure as claimed in claim 4, further comprising:
a cap layer conformally covering the light absorption structure.

6. The semiconductor device structure as claimed in claim 5, wherein the cap layer is in direct contact with the insulating layer.

7. The semiconductor device structure as claimed in claim 1, wherein the first P-type film has an L shape in a cross-sectional view of the first P-type film.

8. The semiconductor device structure as claimed in claim 1, wherein the first P-type film extends into the P-type region.

9. A semiconductor device structure, comprising:
a substrate comprising a P-type region and an N-type region, wherein the P-type region and the N-type region are spaced apart from each other;
a first P-type film in the substrate and connected to the P-type region;
a second P-type film in the substrate and between the first P-type film and the N-type region, wherein the second P-type film is spaced apart from the N-type region; and
a light absorption structure in the substrate and connected between the first P-type film and the second P-type film.

10. The semiconductor device structure as claimed in claim 9, wherein the first P-type film and the second P-type film are made of a same material.

11. The semiconductor device structure as claimed in claim 9, further comprising:
a first insulating structure and a second insulating structure in the substrate, wherein a waveguide portion of the substrate is between the first insulating structure and the second insulating structure, and the waveguide portion is in direct contact with the light absorption structure.

12. The semiconductor device structure as claimed in claim 9, wherein a first top surface of the first P-type film is substantially level with a second top surface of the substrate.

13. The semiconductor device structure as claimed in claim 12, wherein a third top surface of the second P-type film is substantially level with the second top surface of the substrate.

14. A method for forming a semiconductor device structure, comprising:
forming a P-type region and an N-type region in a substrate, wherein the P-type region and the N-type region are spaced apart from each other;
partially removing the substrate between the P-type region and the N-type region to form a first trench in the substrate, wherein the first trench exposes the P-type region;
forming a first P-type film and a second P-type film in the first trench, wherein the first P-type film is on the P-type region exposed by the first trench, the second P-type film is between the first P-type film and the N-type region, the first P-type film and the second P-type film are spaced apart from each other, and the second P-type film and the N-type region are separated from each other by a portion of the substrate; and
forming a light absorption structure in the first trench and over the first P-type film and the second P-type film.

15. The method for forming the semiconductor device structure as claimed in claim 14, further comprising:
forming a first isolation structure and a second isolation structure in the substrate before the P-type region and the N-type region are formed, wherein the first isolation structure passes through a first part of the substrate over the P-type region, and the second isolation structure passes through a second part of the substrate over the N-type region.

16. The method for forming the semiconductor device structure as claimed in claim 15, further comprising:
forming a heavily P-type doped region and a heavily N-type doped region in the substrate, wherein the heavily P-type doped region is over and connected to the P-type region, the first isolation structure is between the heavily P-type doped region and the first P-type film, the heavily N-type doped region is over and connected to the N-type region, and the second isolation structure is between the heavily N-type doped region and the second P-type film.

17. The method for forming the semiconductor device structure as claimed in claim 14, further comprising:
forming an insulating layer over the substrate after the P-type region and the N-type region are formed and before the substrate between the P-type region and the N-type region are partially removed; and
partially removing the insulating layer to form an opening in the insulating layer, wherein the opening is over the first trench in the substrate.

18. The method for forming the semiconductor device structure as claimed in claim 14, wherein the forming of the first P-type film and the second P-type film comprises:
forming a P-type layer in the trench in the substrate; and
partially removing the P-type layer to form a second trench in the P-type layer, wherein the P-type layer is divided into the first P-type film and the second P-type film by the second trench.

19. The method for forming the semiconductor device structure as claimed in claim 18, wherein the P-type layer is formed using an epitaxial process.

20. The method for forming the semiconductor device structure as claimed in claim 14, further comprising:
forming a cap layer over the light absorption structure, wherein the cap layer conformally covers the light absorption structure.
